(19) United States
(12) Patent Application Publication
(10) Pub. No.: US 2026/0214972 A1
(43) Pub. Date: Jul. 23, 2026

(54) SEMICONDUCTOR STRUCTURE AND MANUFACTURING METHOD THEREOF

(71) Applicant: Winbond Electronics Corp., Taichung City (TW)

(72) Inventors: Pin-Hung Chen, Tainan (TW); Po-Chih Fan, Kaohsiung City (TW); Jin-Neng Wu, Kaohsiung City (TW)

(73) Assignee: Winbond Electronics Corp., Taichung City (TW)

(21) Appl. No.: 19/399,630

(22) Filed: Nov. 25, 2025

(30) Foreign Application Priority Data
Jan. 21, 2025 (TW) 114102511

(51) Int. Cl. H10D 84/00; H10D 1/00; H10D 1/68; H10D 62/10

(52) U.S. Cl. CPC H10D 84/212; H10D 1/041; H10D 1/692; H10D 1/716; H10D 62/102

(57) ABSTRACT

A semiconductor structure including a substrate, a first electrode, a first support layer, a high dielectric constant (high-k) dielectric layer, a low dielectric constant (low-k) dielectric layer, and a second electrode is provided. The first electrode is located on the substrate. The first electrode is pillar-shaped. The first support layer is located on the sidewall of the first electrode. The high-k dielectric layer is located on the first electrode and the first support layer. The low-k dielectric layer is located between the first support layer and the high-k dielectric layer and between the first electrode and the high-k dielectric layer. The second electrode is located on the high-k dielectric layer.

### CROSS-REFERENCE TO RELATED APPLICATION

This application claims the priority benefit of Taiwan application serial no. 114102511 filed on Jan. 21, 2025. The entirety of the above-mentioned patent application is hereby incorporated by reference herein and made a part of this specification.

### BACKGROUND

### Technical Field

The invention relates to a semiconductor structure and a manufacturing method thereof, and particularly relates to a semiconductor structure having a low dielectric constant (low-k) dielectric layer and a manufacturing method thereof.

### Description of Related Art

The capacitor is a semiconductor device widely used in the electronic product. However, as the size of the capacitor continues to shrink, how to effectively prevent the leakage current of the capacitor is the goal of continuous efforts.

### SUMMARY

The invention provides a semiconductor structure, which can effectively prevent the leakage current of the capacitor.

The invention provides a semiconductor structure, which includes a substrate, a first electrode, a first support layer, a high dielectric constant (high-k) dielectric layer, a low-k dielectric layer, and a second electrode. The first electrode is located on the substrate. The first electrode is pillar-shaped. The first support layer is located on the sidewall of the first electrode. The high-k dielectric layer is located on the first electrode and the first support layer. The low-k dielectric layer is located between the first support layer and the high-k dielectric layer and between the first electrode and the high-k dielectric layer. The second electrode is located on the high-k dielectric layer.

The invention provides a manufacturing method of a semiconductor structure, which includes the following steps. A substrate is provided. A first electrode is formed on the substrate. The first electrode is pillar-shaped. A first support layer is formed on the sidewall of the first electrode. A low-k dielectric layer is formed on the first electrode and the first support layer. A high-k dielectric layer is formed on the low-k dielectric layer. The low-k dielectric layer is located between the first support layer and the high-k dielectric layer and between the first electrode and the high-k dielectric layer. A second electrode is formed on the high-k dielectric layer.

Based on the above description, in the semiconductor structure and the manufacturing method thereof according to the invention, the capacitor can be formed by the first electrode, the low-k dielectric layer, the high-k dielectric layer, and the second electrode. In addition, the low-k dielectric layer is located between the first support layer and the high-k dielectric layer and between the first electrode and the high-k dielectric layer. Therefore, even if the capacitor is bent, the low-k dielectric layer can effectively prevent the leakage current of the capacitor. Furthermore, the low-k dielectric layer can be used to prevent the leakage current caused by the electron accumulation in the high-k dielectric layer. Moreover, the parasitic capacitance near the first support layer can be reduced by the low-k dielectric layer.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1E are cross-sectional views of a manufacturing process of a semiconductor structure according to some embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

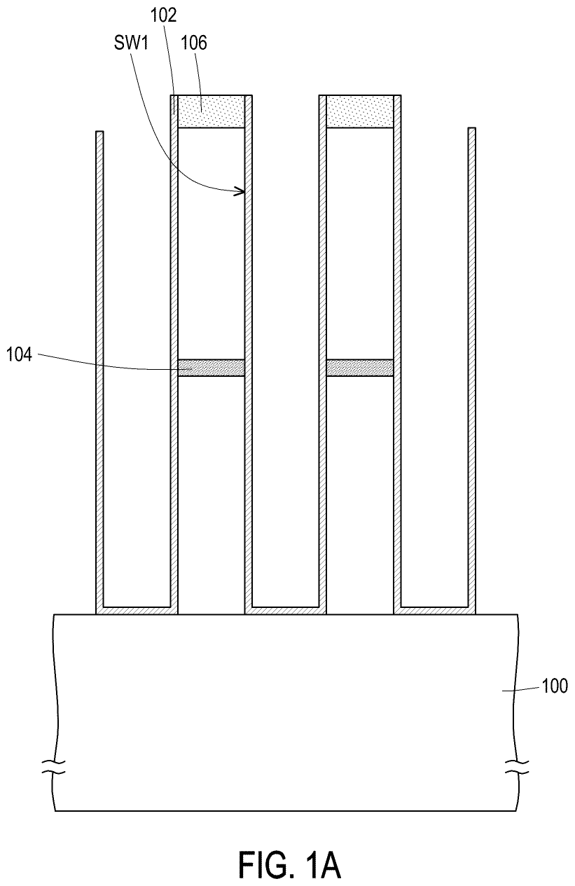

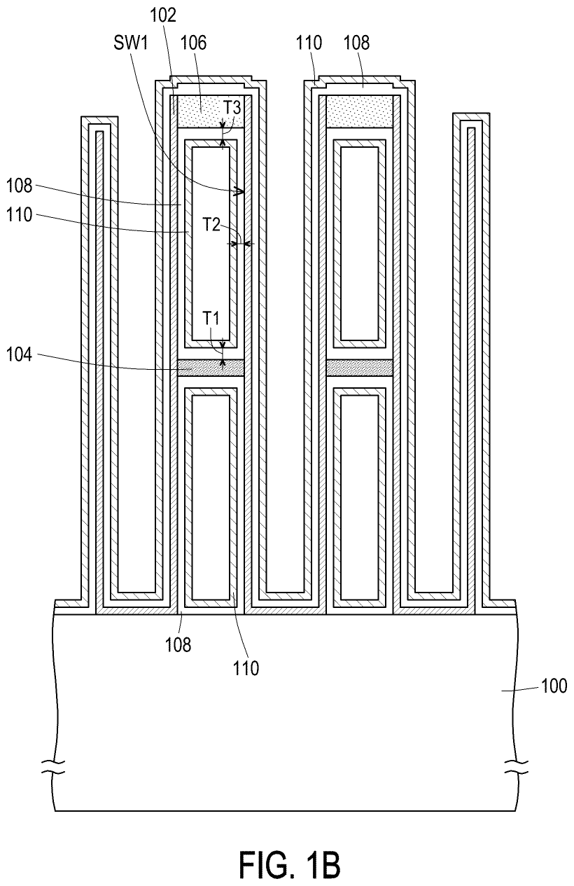

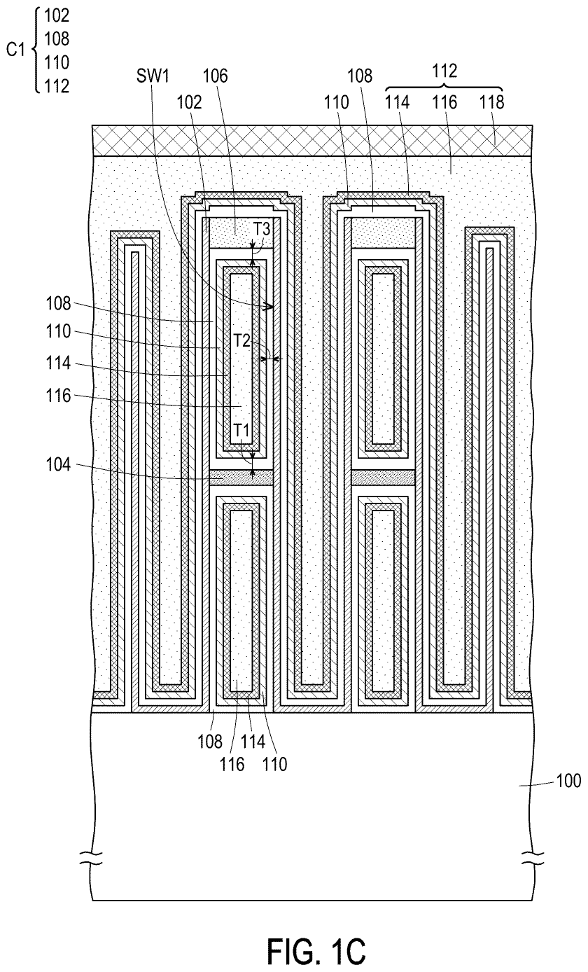

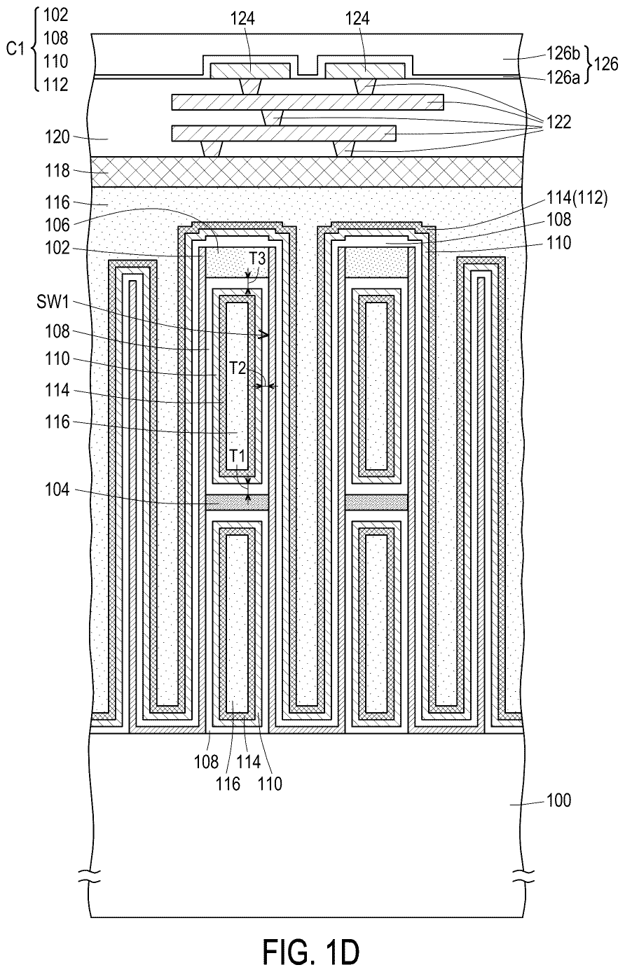

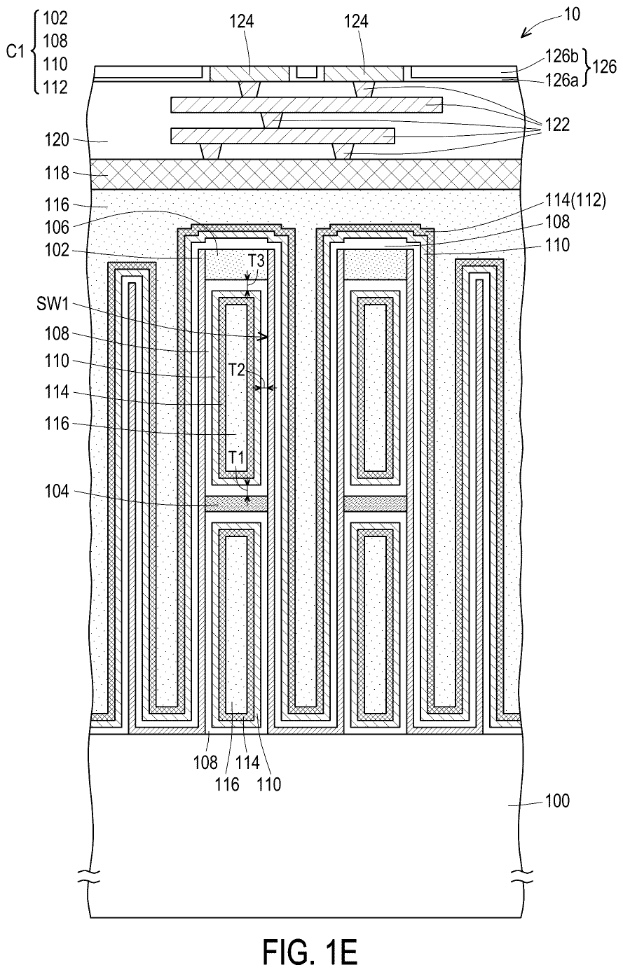

FIG. 1A to FIG. 1E are cross-sectional views of a manufacturing process of a semiconductor structure according to some embodiments of the invention.

Referring to FIG. 1A, a substrate 100 is provided. In some embodiments, the substrate 100 may be a semiconductor substrate such as a silicon substrate. In addition, although not shown in the figures, there may be corresponding components on and/or in the substrate 100 depending on the type of the semiconductor structure. For example, there may be required components (not shown) such as an isolation structure, a doped region and/or a buried word line in the substrate 100, and there may be required components (not shown) such as a dielectric layer and/or an interconnect structure (e.g., bit line and contact) on the substrate 100, and the description thereof is omitted here.

An electrode 102 is formed on the substrate 100. The electrode 102 is pillar-shaped. In some embodiments, the cross-sectional shape of the electrode 102 may be U-shaped. In some embodiments, the material of the electrode 102 is, for example, titanium nitride (TiN). In the present embodiment, the number of the electrodes 102 is, for example, plural, but the invention is not limited thereto. As long as the number of the electrodes 102 is at least one, it falls within the scope of the invention.

A support layer 104 is formed on the sidewall SW1 of the electrode 102. In some embodiments, the material of the support layer 104 is, for example, nitride (e.g., silicon nitride). In some embodiments, a support layer 106 may be formed on the sidewall SW1 of the electrode 102. The support layer 106 may be located directly above the support layer 104. In some embodiments, the material of the support layer 106 is, for example, nitride (e.g., silicon nitride).

Referring to FIG. 1B, a low-k dielectric layer 108 is formed on the electrode 102 and the support layer 104. In some embodiments, the low-k dielectric layer 108 may be further formed on the support layer 106. In some embodiments, the dielectric constant of the low-k dielectric layer 108 may be 3 to 4. In some embodiments, the material of the low-k dielectric layer 108 is, for example, silicon oxycarbide (SiCO). In some embodiments, the method of forming the low-k dielectric layer 108 is, for example, an atomic layer deposition (ALD) method.

In some embodiments, the thickness T1 of the portion of the low-k dielectric layer 108 located on the support layer 104 may be greater than the thickness T2 of the portion of the low-k dielectric layer 108 located on the electrode 102. That is, the portion of the low-k dielectric layer 108 located on the electrode 102 can have a smaller thickness (e.g., thickness T2), so that the low-k dielectric layer 108 has little effect on the capacitance of the capacitor (e.g., capacitor C1 in FIG. 1C). In some embodiments, the thickness T2 of the portion of the low-k dielectric layer 108 located on the electrode 102 may be 72%-88% of the thickness T1 of the portion of the low-k dielectric layer 108 located on the support layer 104.

In some embodiments, the thickness T3 of the portion of the low-k dielectric layer 108 located on the support layer 106 may be greater than the thickness T2 of the portion of the low-k dielectric layer 108 located on the electrode 102. In some embodiments, the thickness T2 of the portion of the low-k dielectric layer 108 located on the electrode 102 may be 72%-88% of the thickness T3 of the portion of the low-k dielectric layer 108 located on the support layer 106.

A high-k dielectric layer 110 is formed on the low-k dielectric layer 108. The low-k dielectric layer 108 is located between the support layer 104 and the high-k dielectric layer 110 and between the electrode 102 and the high-k dielectric layer 110. In some embodiments, the low-k dielectric layer 108 may be further located between the support layer 106 and the high-k dielectric layer 110. In some embodiments, the dielectric constant of the high-k dielectric layer 110 may be 20 to 40. In some embodiments, the material of the high-k dielectric layer 110 is, for example, zirconium oxide (ZrO), aluminum oxide (AlO), or a combination thereof.

Referring to FIG. 1C, an electrode 112, a conductive layer 116, and a conductive layer 118 are formed on the high-k dielectric layer 110. In some embodiments, a capacitor C1 may be formed by the electrode 102, the low-k dielectric layer 108, the high-k dielectric layer 110, and the electrode 112. The electrode 112 may be a single-layer structure or a multilayer structure. In the present embodiment, the electrode 112 is, for example, a single-layer structure, but the invention is not limited thereto. For example, the electrode 112 may include a conductive layer 114. The conductive layer 114 is located on the high-k dielectric layer 110. In some embodiments, the material of the conductive layer 114 is, for example, titanium nitride. The conductive layer 116 is located on the conductive layer 114. In some embodiments, the material of the conductive layer 116 is, for example, a doped semiconductor material such as boron-doped silicon-germanium (BSiGe) or doped polysilicon. The conductive layer 118 is located on the conductive layer 116. In some embodiments, the material of the conductive layer 118 is metal such as tungsten.

Referring to FIG. 1D, a dielectric layer 120 and an interconnect structure 122 may be formed on the conductive layer 118. In some embodiments, the dielectric layer 120 may be a multilayer structure. In some embodiments, the material of the dielectric layer 120 is, for example, oxide (e.g., silicon oxide). The interconnect structure 122 is located in the dielectric layer 120. In some embodiments, the material of the interconnect structure 122 is, for example, copper, tungsten, or a combination thereof. In some embodiments, the dielectric layer 120 and the interconnect structure 122 may be formed by an interconnect process.

A conductive layer 124 may be formed on the dielectric layer 120 and the interconnect structure 122. The conductive layer 124 may be electrically connected to the interconnect structure 122. In some embodiments, the conductive layer 124 may serve as a pad. In some embodiments, the material of the conductive layer 124 is, for example, aluminum.

A dielectric layer 126 may be formed on the dielectric layer 120 and the conductive layer 124. The dielectric layer 126 may be a multilayer structure. For example, the dielectric layer 126 may include a dielectric layer 126a and a dielectric layer 126b, but the invention is not limited thereto. As long as the dielectric layer 126 is a multilayer structure, it falls within the scope of the invention. In some embodiments, the dielectric layer 126 may be formed by performing deposition processes. Therefore, the formation of voids in the dielectric layer 126 can be prevented. In some embodiments, the deposition process is, for example, a chemical vapor deposition process, an ALD process, or a high density plasma chemical vapor deposition (HDP CVD) method.

Referring to 1E, a portion of the dielectric layer 126 may be removed to expose the conductive layer 124. In some embodiments, the method of removing the portion of the dielectric layer 126 is, for example, a chemical mechanical polishing (CMP) method or an etch-back method.

Hereinafter, the semiconductor structure 10 of the above embodiment is described with reference to FIG. 1E. In addition, although the method for forming the semiconductor structure 10 is described by taking the above method as an example, the invention is not limited thereto.

Referring to 1E, a semiconductor structure 10 includes a substrate 100, an electrode 102, a support layer 104, a high-k dielectric layer 110, a low-k dielectric layer 108, and an electrode 112. The electrode 102 is located on the substrate 100. The electrode 102 is pillar-shaped. The support layer 104 is located on the sidewall SW1 of the electrode 102. The high-k dielectric layer 110 is located on the electrode 102 and the support layer 104. The low-k dielectric layer 108 is located between the support layer 104 and the high-k dielectric layer 110 and between the electrode 102 and the high-k dielectric layer 110. The electrode 112 is located on the high-k dielectric layer 110. In some embodiments, the semiconductor structure 10 may further include a support layer 106. The support layer 106 is located directly above the support layer 104. In some embodiments, the low-k dielectric layer 108 may be further located on the support layer 106. In some embodiments, the low-k dielectric layer 108 may be further located between the support layer 106 and the high-k dielectric layer 110.

The semiconductor structure 10 may further include a dielectric layer 120, an interconnect structure 122, a conductive layer 124, and a dielectric layer 126. The dielectric layer 120 is located on the conductive layer 118. The interconnect structure 122 is located in the dielectric layer 120. The conductive layer 124 is located on the dielectric layer 120 and the interconnect structure 122. The dielectric layer 126 is located on the dielectric layer 120 and between the adjacent conductive layers 124. In addition, the details (e.g., the material and the forming method) of the components in the semiconductor structure 10 have been described in detail in the above embodiments, and the description thereof is not repeated here.

Based on the above embodiments, in the semiconductor structure 10 and the manufacturing method thereof, the capacitor C1 can be formed by the electrode 102, the low-k dielectric layer 108, the high-k dielectric layer 110, and the electrode 112. In addition, the low-k dielectric layer 108 is located between the support layer 104 and the high-k dielectric layer 110 and between the electrode 102 and the high-k dielectric layer 110. Therefore, even if the capacitor C1 is bent, the low-k dielectric layer 108 can effectively prevent the leakage current of the capacitor C1. Furthermore, the low-k dielectric layer 108 can be used to prevent the leakage current caused by the electron accumulation in the high-k dielectric layer 110. Moreover, the parasitic capacitance near the support layer 104 can be reduced by the low-k dielectric layer 108.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a substrate;
a first electrode located on the substrate, wherein the first electrode is pillar-shaped;
a first support layer located on a sidewall of the first electrode;
a high dielectric constant (high-k) dielectric layer located on the first electrode and the first support layer;
a low dielectric constant (low-k) dielectric layer located between the first support layer and the high-k dielectric layer and between the first electrode and the high-k dielectric layer; and
a second electrode located on the high-k dielectric layer.

2. The semiconductor structure according to claim 1, wherein a thickness of a portion of the low-k dielectric layer located on the first support layer is greater than a thickness of a portion of the low-k dielectric layer located on the first electrode.

3. The semiconductor structure according to claim 1, wherein a thickness of a portion of the low-k dielectric layer located on the first electrode is 72%-88% of a thickness of a portion of the low-k dielectric layer located on the first support layer.

4. The semiconductor structure according to claim 1, wherein a material of the high-k dielectric layer comprises zirconium oxide (ZrO), aluminum oxide (AlO), or a combination thereof.

5. The semiconductor structure according to claim 1, wherein a material of the low-k dielectric layer comprises silicon oxycarbide.

6. The semiconductor structure according to claim 1, further comprising:
a second support layer located directly above the first support layer, wherein the low-k dielectric layer is further located on the second support layer.

7. The semiconductor structure according to claim 6, wherein the low-k dielectric layer is further located between the second support layer and the high-k dielectric layer.

8. The semiconductor structure according to claim 6, wherein a thickness of a portion of the low-k dielectric layer located on the second support layer is greater than a thickness of a portion of the low-k dielectric layer located on the first electrode.

9. The semiconductor structure according to claim 6, wherein a thickness of a portion of the low-k dielectric layer located on the first electrode is 72%-88% of a thickness of a portion of the low-k dielectric layer located on the second support layer.

10. The semiconductor structure according to claim 1, wherein a material of the first electrode comprises titanium nitride.

11. The semiconductor structure according to claim 1, wherein a material of the first support layer comprises nitride.

12. The semiconductor structure according to claim 1, wherein a material of the second electrode comprises titanium nitride.

13. A manufacturing method of a semiconductor structure, comprising:
providing a substrate;
forming a first electrode on the substrate, wherein the first electrode is pillar-shaped;
forming a first support layer on a sidewall of the first electrode;
forming a low-k dielectric layer on the first electrode and the first support layer;
forming a high-k dielectric layer on the low-k dielectric layer, wherein the low-k dielectric layer is located between the first support layer and the high-k dielectric layer and between the first electrode and the high-k dielectric layer; and
forming a second electrode on the high-k dielectric layer.

14. The manufacturing method of the semiconductor structure according to claim 13, wherein a method of forming the low-k dielectric layer comprises an atomic layer deposition method.

15. The manufacturing method of the semiconductor structure according to claim 13, wherein a thickness of a portion of the low-k dielectric layer located on the first support layer is greater than a thickness of a portion of the low-k dielectric layer located on the first electrode.

16. The manufacturing method of the semiconductor structure according to claim 13, wherein a thickness of a portion of the low-k dielectric layer located on the first electrode is 72%-88% of a thickness of a portion of the low-k dielectric layer located on the first support layer.

17. The manufacturing method of the semiconductor structure according to claim 13, further comprising:
forming a second support layer on the sidewall of the first electrode, wherein the second support layer is located directly above the first support layer, and the low-k dielectric layer is further formed on the second support layer.

18. The manufacturing method of the semiconductor structure according to claim 17, wherein the low-k dielectric layer is further located between the second support layer and the high-k dielectric layer.

19. The manufacturing method of the semiconductor structure according to claim 17, wherein a thickness of a portion of the low-k dielectric layer located on the second support layer is greater than a thickness of a portion of the low-k dielectric layer located on the first electrode.

20. The manufacturing method of the semiconductor structure according to claim 17, wherein a thickness of a portion of the low-k dielectric layer located on the first electrode is 72%-88% of a thickness of a portion of the low-k dielectric layer located on the second support layer.
